(19) United States
(12) Patent Application Publication
(10) Pub. No.: US 2006/0231850 A1
(43) Pub. Date: Oct. 19, 2006

(54) Semiconductor laser diode having ridge portion and method of manufacturing the same

(75) Inventors: Tan Sakong, Suwon-si (KR); Tae-hoon Jang, Seoul (KR); Joong-kon Son, Seoul (KR); Han-youl Ryu, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/350,936

(22) Filed: Feb. 10, 2006

(30) Foreign Application Priority Data
Apr. 15, 2005 (KR) 10-2005-0031407

(51) Int. Cl. H01L 33/00

(52) U.S. Cl. 257/96

(57) ABSTRACT

Provided is a semiconductor laser diode having a ridge portion and a method of manufacturing the semiconductor laser diode. The semiconductor laser diode includes: a first clad layer, an active layer formed on the first clad layer, a second clad layer formed on the active layer and having a stripe shaped ridge portion; and a buried layer formed of AlGaInN and grown on the second clad layer except for a region of an upper surface of the ridge portion.

### CROSS-REFERENCE TO RELATED PATENT APPLICATION

This application claims the benefit of Korean Patent Application No. 10-2005-0031407, filed on Apr. 15, 2005, in the Korean Intellectual Property Office, the disclosure of which is incorporated herein in its entirety by reference.

### BACKGROUND OF THE INVENTION

1. Field of the Invention

The present invention relates to a semiconductor laser diode and a method of manufacturing the same, and more particularly, to a semiconductor laser diode having a heat discharge layer on a side of a ridge portion and a method of manufacturing the same.

2. Description of the Related Art

Semiconductor lasers are widely used for transmitting, recording, or reading data in communication devices, such as optical communication devices, or in electronic devices, such as compact disc players (CDPs) or digital video disc players (DVDPs).

As the use of the semiconductor lasers has increased, semiconductor laser diodes having a low critical current value and a ridge portion that blocks a multiple transverse mode generation, have been developed.

A conventional semiconductor laser diode having the ridge portion includes a buried layer that is formed of an insulating layer and defines a ridge region.

The buried layer formed of an insulating layer has low thermal conductivity and thus it does not efficiently discharge heat generated from an active layer. Accordingly, the active layer may be degraded.

To effectively discharge heat generated from the active layer, a technique of manufacturing the buried layer using AlGaN has been disclosed in U.S. Pat. No. 6,620,641. However, when the AlGaN is deposited, an excessive pressure must be applied to a reactor for separating nitrogen atoms N from ammonia, which is used as a nitrogen atom source since the separation of nitrogen atoms N from ammonia is difficult. Also, vacancies in the AlGaN that are not filled with the nitrogen atoms N may degrade the optical characteristics of the single-crystalline AlGaN.

### SUMMARY OF THE INVENTION

The present invention provides a semiconductor laser diode having a ridge portion having a buried layer that has high heat discharge efficiency and a favorable single-crystalline growth state.

Also, the present invention provides a semiconductor laser diode that can maintain a single-transverse mode under a high generation output using a buried layer formed of a material, an index of which can be easily controlled.

The present invention also provides a method of manufacturing the semiconductor laser diode.

According to an aspect of the present invention, there is provided a semiconductor laser diode comprising: a first clad layer; an active layer formed on the first clad layer; a second clad layer formed on the active layer and having a stripe shaped ridge portion; and a buried layer formed of AlGaInN and grown on the second clad layer except for a region of an upper surface of the ridge portion.

The buried layer may be grown to a single-crystalline state.

The buried layer may be an Alₓ₁Ga_{y1}In_{z1}N layer, where x1 is 0.1-0.2, z1 is 0.001 or less, and x1+y1+z1=1.

The buried layer may further comprise an Alₓ₂Ga_{y2}In_{z2}N layer under the Alₓ₁Ga_{y1}In_{z1}N layer, where x2 is approximately 0.05, z2 is 0.005 or less, and x2+y2+z2=1.

The buried layer may further comprise an Alₓ₃Ga_{y3}N layer on the Alₓ₁Ga_{y1}In_{z1}N layer, where x3 is approximately 0.05 and x3+y3=1.

The semiconductor laser diode may further comprise an Alₓ₄Ga_{y4}N layer between the Alₓ₂Ga_{y2}In_{z2}N layer and the Alₓ₁Ga_{y1}In_{z1}N layer, where x4 is approximately 0.05 and x4+y4=1.

The Alₓ₁Ga_{y1}In_{z1}N layer may be formed by alternately stacking at least two layers having different composition from each other.

The Alₓ₁Ga_{y1}In_{z1}N layer may be formed by alternately stacking a Si-doped layer and an Mg-doped layer.

The Alₓ₁Ga_{y1}In_{z1}N layer may be formed by alternately stacking an undoped layer, a Si-doped layer, and an Mg-doped layer.

According to another aspect of the present invention, there is provided a method of manufacturing a semiconductor laser diode, the method comprising: forming an active layer on a first clad layer; forming a second clad layer having a ridge stripe structure, on the active layer; and forming a buried layer comprised of AlGaInN on the second clad layer except for the upper surface of the ridge portion, wherein the forming of the buried layer comprises: forming a mask layer on the upper surface of the ridge portion; and forming the buried layer grown to single-crystalline by depositing an Alₓ₁Ga_{y1}In_{z1}N layer on the second clad layer except for a region covered by the mask layer, where x1 is 0.1-0.2, z1 is 0.001 or less, and x1+y1+z1=1.

The Alₓ₁Ga_{y1}In_{z1}N layer may be deposited to a thickness of 5000 Å or less at a temperature range of 700 to 950° C.

The Alₓ₁Ga_{y1}In_{z1}N layer may be deposited at a temperature of approximately 900° C.

### BRIEF DESCRIPTION OF THE DRAWINGS

The application file contains two drawings executed in color. Copies of this patent or patent application publication with color drawings will be provided by the Office upon request and payment of the necessary fee.

The above and other features and advantages of the present invention will become more apparent by describing in detail exemplary embodiments thereof with reference to the attached drawings in which:

FIG. 1 is a cross-sectional view of a semiconductor laser diode according to an embodiment of the present invention;

FIG. 2 is a schematic drawing of a buried layer according to an embodiment of the present invention;

FIGS. 3 through 8 are cross-sectional views for explaining a method of manufacturing a semiconductor laser diode according to an embodiment of the present invention;

FIG. 9 is a SEM image of an AlGaInN layer grown on a p-clad layer according to an embodiment of the present invention;

FIG. 10 is an AFM image of an AlGaInN layer grown on a p-clad layer according to an embodiment of the present invention;

FIG. 11 is a graph showing I-V characteristic curves of a semiconductor laser diode according to an embodiment of the present invention; and

FIG. 12 is a graph showing optical characteristics of a semiconductor laser diode in case of a buried layer is not grown (As-Growth) and in case of the buried layer is grown (Re-Growth) according to an embodiment of the present invention.

### DETAILED DESCRIPTION OF THE INVENTION

A semiconductor laser diode having a ridge portion and a method of manufacturing the semiconductor laser diode having the ridge portion according to the present invention will now be described more fully with reference to the accompanying drawings in which exemplary embodiments of the invention are shown. In the drawings, the thicknesses of layers and regions are exaggerated for clarity.

A semiconductor laser diode according to an embodiment of the present invention will now be described.

Referring to FIG. 1, an n-GaN contact layer 12 is formed on a sapphire substrate 10. The n-GaN contact layer 12 may be divided into a first region R1 and a second region R2. An n-AlGaN/GaN clad layer 24, an n-GaN waveguide layer 26, an InGaN active layer 28, a p-GaN waveguide layer 30, and a p-AlGaN/GaN clad layer 32 are sequentially formed on the first region R1. The n-AlGaN/GaN clad layer 24 and the p-AlGaN/GaN clad layer 32 have lower refractive indexes than the refractive indexes of the n-GaN waveguide layer 26 and the p-GaN waveguide layer 30. The n-GaN waveguide layer 26 and the p-GaN waveguide layer 30 have lower refractive indexes than the refractive index of the InGaN active layer 28. The p-AlGaN/GaN clad layer 32 has a ridge portion protruded in a stripe shape on a central upper portion thereof. A p-GaN contact layer 34 is formed on an upper surface of the ridge portion of the p-AlGaN/GaN clad layer 32. A buried layer 36 grown to a single-crystalline is formed on a surface of the p-AlGaN/GaN clad layer 32 except for the surface that does not covered by the p-GaN contact layer 34. A p-type electrode 38 contacting the p-GaN contact layer 34 is formed on the buried layer 36.

The p-AlGaN/GaN clad layer 32 having the ridge portion limits a resonance region for generating a laser from the InGaN active layer 28 by limiting an inputted current. Accordingly, a multiple transverse mode generation is blocked.

A height of the second region R2 of the n-GaN contact layer 12 is smaller than a height of the first region R1, and an n-type electrode 40 is formed on the second region R2.

The buried layer 36 is formed of AlGaInN having a high thermal transfer coefficient. The AlGaInN layer 36 is formed of a single-crystalline grown from the p-AlGaN/GaN clad layer 32.

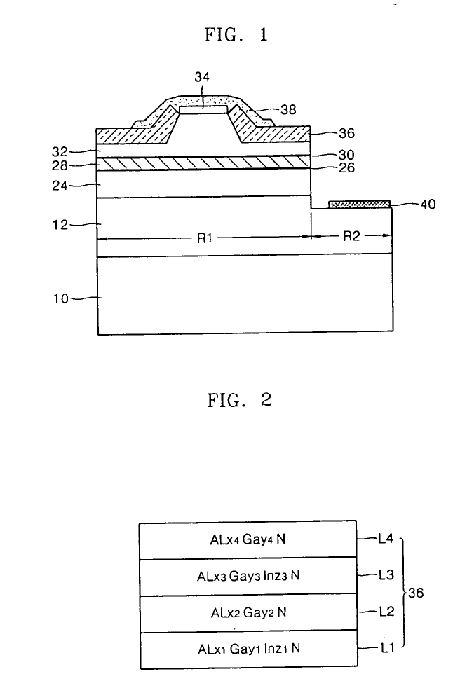

FIG. 2 is a schematic drawing of a buried layer according to an embodiment of the present invention.

Referring to FIG. 2, the buried layer 36 may include four layers. A first layer L1 is formed to a thickness of approximately 500 Å or less at a temperature of 600-800° C., preferably, at 770° C., and has a composition formula of Alₓ₁Ga_{y1}In_{z1}N. Here, x1 is approximately 0.05, z1 is 0.005 or less, and x1+y1+z1=1. The first layer L1 is a protection layer for protecting the active layer 28 from current leakage when the active layer 28 is degraded and dislocated by thermal impact at a high temperature. Accordingly, the first layer L1 is grown at a relatively low temperature similar to the formation temperature of the active layer 28. Here, In is included for matching the active layer 28.

A second layer L2 is formed to a thickness of approximately 500 Å or less at a temperature of 700-950° C., preferably, at 900° C., and has a composition formula of Alₓ₂Ga_{y2}N. The second layer L2 is formed to protect the first layer L1 that includes In. The second layer L2 is to protect the layer including In so that the crystal characteristics of this layer do not degrade when the layer including In is exposed for a prolonged period of time to a higher temperature than a growing temperature of the layer including In without the protection layer.

A third layer L3 is formed to a thickness of approximately 5000 Å or less at a temperature of 700-950° C., preferably, at 900° C., and has a composition formula of Alₓ₃Ga_{y3}In_{z3}N. Here, x3 is approximately 0.1-0.2, z3 is 0.001 or less, and x3+y330 z3=1. The third layer L3 is a main layer of the buried layer 36, and improves the quality of a single-crystalline grown by removing Ga vacancies using In. Accordingly, the third layer L3 improves the optical characteristics of the semiconductor laser diode. The third layer L3 can be grown to a multiple layer by alternately stacking a layer having a different composition of an AlGaInN layer. Also, to increase a breakdown voltage, Si and Mg can be alternately doped. Also, the third layer L3 may be formed by repeatedly stacking a three-layer stack composed of an undoped layer, a Si-doped layer, and an Mg-doped layer or an undoped layer, an Mg-doped layer, and a Si-doped layer.

A fourth layer L4 is formed to a thickness of approximately 500 Å or less at a temperature of 700-950° C., preferably, at 900° C., and has a composition formula of Alₓ₄Ga_{y4}N. Here, x4 is approximately 0.05, and x4+y4=1. The fourth layer L4 is formed to protect the third layer L3 including In.

The first through fourth layers L1, L2, L3, and L4 can be doped with Si or Mg.

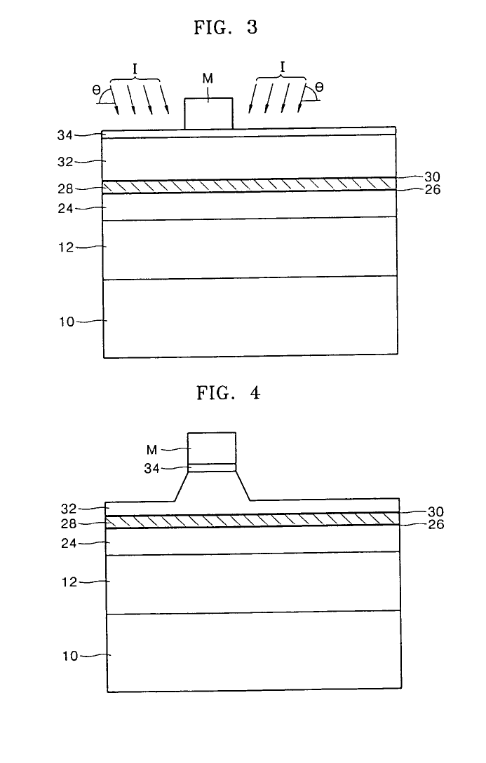

A method of manufacturing the semiconductor laser diode according to an embodiment of the present invention will now be described. Like reference numerals in FIGS. 3 through 8 denote the same elements as in FIG. 1, thus their descriptions will be omitted.

Referring to FIG. 3, an n-GaN contact layer 12, an n-AlGaN/GaN clad layer 24, an n-GaN waveguide layer 26, an InGaN active layer 28, a p-GaN waveguide layer 30, a p-AlGaN/GaN clad layer 32, and a p-GaN contact layer 34 are formed on a sapphire substrate 10. After a mask layer (not shown) is formed on the p-GaN contact layer 34, a mask pattern M is formed by patterning the mask layer. The mask pattern M covers a predetermined region of the p-GaN contact layer 34 and exposes the rest of the regions of the p-GaN contact layer 34. The mask pattern M can be formed of a silicon oxide SiO₂film. The p-GaN contact layer 34 and the p-AlGaN/GaN clad layer 32 are sequentially etched using the mask pattern M as an etch mask, preferably by a dry etching. More preferably, the p-GaN contact layer 34 may be etched by radiating an etching ion beam I to the p-GaN contact layer 34 at a predetermined oblique angle θ. The ion beam I may be radiated with an oblique angle of 10° to 70°. The oblique radiation condition can be attained by controlling a position of the etching equipment or by controlling a position of a wafer stage. The etching is performed until the exposed portion of the p-GaN contact layer 34 is etched and the exposed portion of the p-AlGaN/GaN clad layer 32 is etched to a predetermined thickness. In the above etching process, a portion of the p-AlGaN/GaN clad layer 32 except for a region covered by the mask pattern M is etched to a predetermined depth. As a result, as depicted in FIG. 4, the portion of the p-AlGaN/GaN clad layer 32 covered by the mask pattern M becomes a protruded ridge portion.

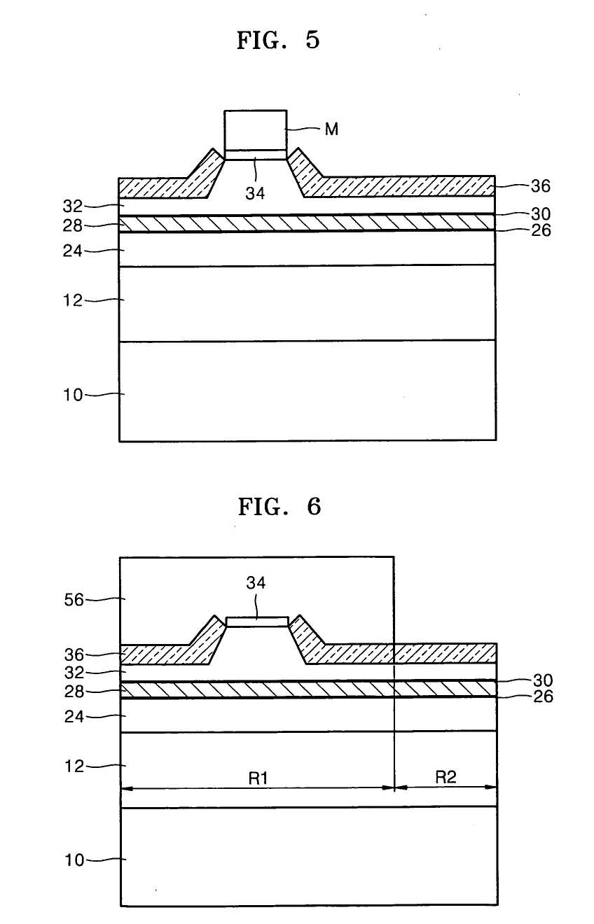

Referring to FIG. 5, a buried layer 36 is grown on the p-clad layer 32. The buried layer 36 may have the same structure as depicted in FIG. 2. The buried layer 36 is formed of an AlGaInN layer having high thermal transfer coefficient. The buried layer 36 is composed of a single-crystalline grown from the region of the p-clad layer 32 except for a region covered by the mask pattern M which is an amorphous layer.

A first layer L1 is formed to a thickness of approximately 500 Å or less at a temperature range of 600 to 800° C., preferably, at 770° C., and has a composition formula of Alₓ₁Ga_{y1}In_{z1}N. Here, x1 is approximately 0.05, z1 is 0.005 or less, and x1+y1+z1 =1.

A second layer L2 is formed to a thickness of approximately 500 Å or less at a temperature range of 700 to 950° C., preferably, at 900° C., and has a composition formula of Alₓ₂Ga_{y2}N. Here, x2 is approximately 0.05 and x2+y2=1. The second layer L2 is formed to protect the first layer L1 including In.

A third layer L3 is formed to a thickness of approximately 5000 Å or less at a temperature range of 700 to 950° C., preferably, at 900° C., and has a composition formula of Alₓ₃Ga_{y3}In_{z3}N. Here, x3 is approximately 0.1-0.2, z3 is 0.001 or less, and x3+y3+z3=1. The third layer L3 can be grown to a multiple layer by alternately stacking a layer having a different composition of an AlGaInN layer. Also, to increase a breakdown voltage, Si and Mg can be alternately doped to the third layer L3. Also, the third layer L3 may be formed by repeatedly stacking a three-layer stack composed of an undoped layer, a Si-doped layer, and an Mg-doped layer or an undoped layer, an Mg-doped layer, and a Si-doped layer.

A fourth layer L4 is formed to a thickness of approximately 500 Å or less at a temperature range of 700 to 950° C., preferably, at 900° C., and has a composition formula of Alₓ₄Ga_{y4}N. Here, x4 is approximately 0.05, and x4+y4=1. Afterward, the mask pattern M may be removed.

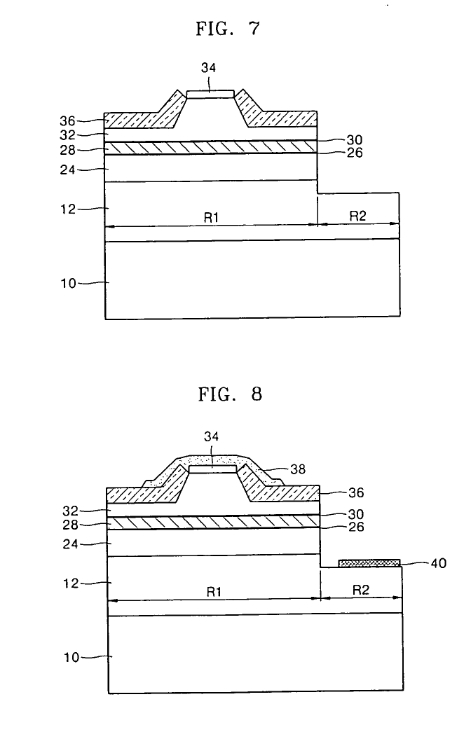

Referring to FIG. 6, a first region R1 that includes the ridge portion and a second region R2 that does not include the ridge portion are defined on the p-clad layer 32. After a photosensitive film (not shown) is coated on the p-AlGaN/GaN clad layer 32 to a thickness enough to cover the ridge portion, a photosensitive pattern 56 that exposes the second region R2 is formed by patterning the photosensitive film. Layers under the region are consecutively etched using the photosensitive pattern 56 as an etch mask. At this time, the etching is continued until a portion of the n-GaN contact layer 12 corresponding to the second region R2 is etched to a predetermined thickness. The photosensitive pattern 56 is removed, and as depicted in FIG. 7, a step between the first region R1 and the second region R2 of the n-GaN contact layer 12 is formed.

Referring to FIG. 8, a p-type electrode 38 is formed on a buried layer 36 and a p-contact layer 34, and an n-type electrode 40 is formed on the second region R2 of the n-GaN contact layer 12.

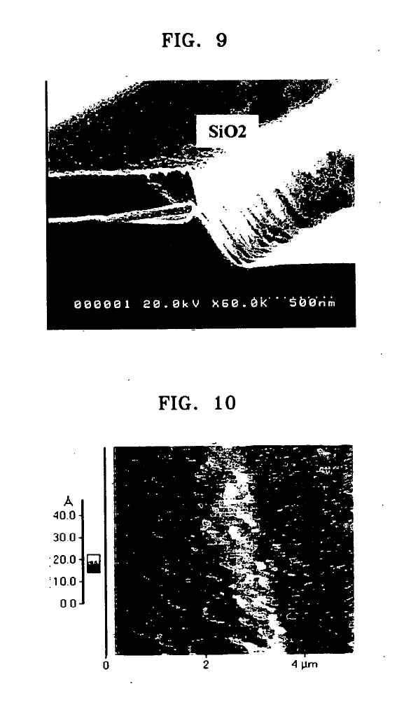

FIG. 9 is a SEM image of an AlGaInN layer grown on the p-clad layer 32 according to an embodiment of the present invention. Referring to FIG. 9, the AlGaInN layer is grown on regions of the p-clad layer 32 except for a region on which the mask formed of SiO₂ is formed.

FIG. 10 is an AFM image of an AlGaInN layer grown on the p-clad layer 32 according to an embodiment of the present invention. Referring to FIG. 10, grain boundaries which indicate polycrystalline are not shown, and this explains that the AlGaInN layer grown to a single-crystalline.

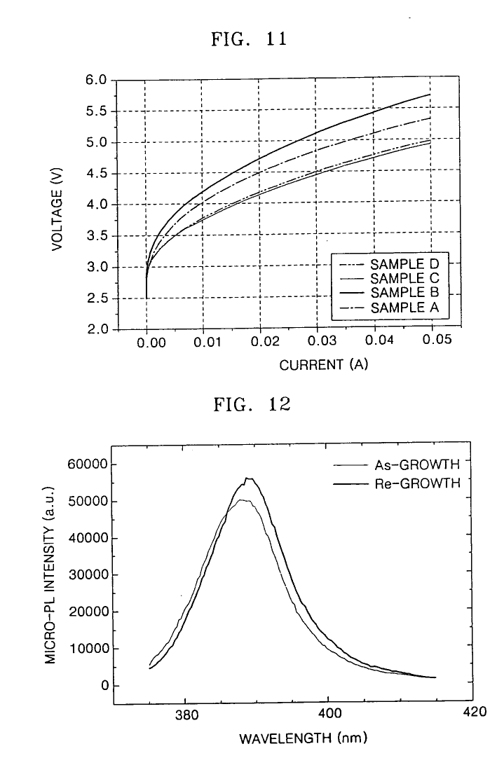

FIG. 11 is a graph showing I-V characteristics of a semiconductor laser diode having the AlGaInN layer as a buried layer according to an embodiment of the present invention. A leakage current is not observed in the I-V characteristics of four samples. This indicates that the AlGaInN is grown with favorable current characteristics.

FIG. 12 is a graph showing optical characteristics of a semiconductor laser diode in case of a buried layer is not grown (As-Growth) and in case of the buried layer is grown (Re-Growth) according to an embodiment of the present invention. Referring to FIG. 12, the emission efficiencies of the semiconductor laser diode with or without the buried layer 36 are almost the same. That is, the buried layer 36 does not affect the optical characteristics of the semiconductor laser diode. Accordingly, the improvement of heat discharge characteristics through the buried layer 36 allows the manufacturing of a stable semiconductor laser diode.

As described above, the buried layer formed of AlGaInN according to the present invention blocks a multiple transverse mode emission of a semiconductor laser diode, and increases a lifespan of an active layer due to a smooth heat discharge and the optical characteristics of the semiconductor laser diode.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor laser diode comprising:
a first clad layer;
an active layer formed on the first clad layer;
a second clad layer formed on the active layer and having a stripe shaped ridge portion; and
a buried layer formed of AlGaInN and grown on the second clad layer except for a region of an upper surface of the ridge portion.

2. The semiconductor laser diode of claim 1, wherein the buried layer is grown to a single-crystalline state.

3. The semiconductor laser diode of claim 1, wherein the buried layer is an Alₓ₁Ga_{y1}In_{z1}N layer, where x1 is 0.1-0.2, z1 is 0.001 or less, and x1+y1+z1=1.

4. The semiconductor laser diode of claim 3, wherein the Alₓ₁Ga_{y1}In_{z1}N layer is grown at a temperature range of 700 to 950° C.

5. The semiconductor laser diode of claim 4, wherein the Alₓ₁Ga_{y1}In_{z1}N layer is grown at a temperature of approximately 900° C.

6. The semiconductor laser diode of claim 4, wherein the buried layer further comprises an Alₓ₂Ga_{y2}In_{z2}N layer under the Alₓ₁Ga_{y1}In_{z1}N layer, where x2 is approximately 0.05, z2 is 0.005 or less, and x2+y2+z2=1.

7. The semiconductor laser diode of claim 6, wherein the Alₓ₂Ga_{y2}In_{z2}N layer is grown at a temperature of approximately 770° C.

8. The semiconductor laser diode of claim 7, wherein the buried layer further comprises an Alₓ₃Ga_{y3}N layer on the Alₓ₁Ga_{y1}In_{z1}N layer, where x3 is approximately 0.05 and x3+y3=1.

9. The semiconductor laser diode of claim 8, further comprising an Alₓ₄Ga_{y4}N layer between the Alₓ₂Ga_{y2}In_{z2}N layer and the Alₓ₁Ga_{y1}In_{z1}N layer, where x4 is approximately 0.05 and x4+y4=1.

10. The semiconductor laser diode of claim 3, wherein the Alₓ₁Ga_{y1}In_{z}N layer is formed by alternately stacking at least two layers having different compositions from each other.

11. The semiconductor laser diode of claim 10, wherein the Alₓ₁Ga_{y1}In_{z1}N layer is formed of an alternate stack comprising a layer doped with Si and a layer doped with Mg.

12. The semiconductor laser diode of claim 10, wherein the Alₓ₁Ga_{y1}In_{z1}N layer is formed of an alternate stack comprising an undoped layer, a Si-doped layer, and an Mg-doped layer.

13. A method of manufacturing a semiconductor laser diode, comprising:
forming an active layer on a first clad layer;
forming a second clad layer having a ridge stripe structure on the active layer; and
forming a buried layer comprised of AlGaInN on the second clad layer except for the upper surface of the ridge portion, wherein
the forming of the buried layer comprises:
forming a mask layer on the upper surface of the ridge portion; and
forming the buried layer grown to a single-crystalline by depositing an Alₓ₁Ga_{y1}In_{z1}N layer on the second clad layer except for a region covered by the mask layer, where x1 is 0.1-0.2, z1 is 0.001 or less, and x1+y1+z1=1.

14. The method of claim 13, wherein the Alₓ₁Ga_{y1}In_{z1}N layer is deposited to a thickness of 5000 Å or less at a temperature range of 700 to 950° C.

15. The method of claim 14, wherein the Alₓ₁,Ga_{y1}In_{z1}N layer is deposited at a temperature of approximately 900° C.

16. The method of claim 14, wherein the forming of the buried layer further comprises depositing an Alₓ₂Ga_{y2}In_{z2}N layer to a thickness of 500 Å or less at a temperature of approximately 770° C. under the Alₓ₁Ga_{y1}In_{z1}N layer, where x2 is approximately 0.05, z2 is 0.005 or less, and x2+y2+z2=1.

17. The method of claim 16, wherein the forming of the buried layer further comprises depositing an Alₓ₃Ga_{y3}N layer to a thickness of 500 Å or less at a temperature of approximately 900° C. on the Alₓ₁Ga_{y1}In_{z1}N layer, where x3 is approximately 0.05 and x3+y3=1.

18. The method of claim 17, wherein the forming of the buried layer further comprises depositing an Alₓ₄Ga_{y4}N layer to a thickness of 500 Å or less at a temperature of approximately 900° C. between the Alₓ₂Ga_{y2}In_{z2}N layer and the Alₓ₁Ga_{y1}In_{z1}N layer, where x4 is approximately 0.05 and x4+y4=1.

19. The method of claim 13, wherein the Alₓ₁Ga_{y1}In_{z1}N layer is formed by alternately depositing at least two layers having different composition from each other.

20. The method of claim 19, wherein the Alₓ₁,Ga_{y1}In_{z1}N layer is formed by alternately stacking a Si-doped layer and an Mg-doped layer.

21. The method of claim 10, wherein the Alₓ₁Ga_{y1}In_{z1}N layer is formed by alternately stacking an undoped layer, a Si-doped layer, and an Mg-doped layer.
